(19) United States
(12) Patent Application Publication
(10) Pub. No.: US 2016/0099184 A1
(43) Pub. Date: Apr. 7, 2016

(54) SEMICONDUCTOR CHIP AND METHOD OF ESTIMATING CAPABILITY OF SEMICONDUCTOR MANUFACTURING SYSTEM

(71) Applicant: UNITED MICROELECTRONICS CORP., Hsin-Chu City (TW)

(72) Inventors: Wei-Chi Lee, Tainan City (TW); Yu-Lin Wang, Taipei City (TW); Chun-Chieh Chang, Tainan City (TW); Tzu-Feng Chang, Pingtung County (TW); Po-Peng Lin, Tainan City (TW)

(21) Appl. No.: 14/509,032

(22) Filed: Oct. 7, 2014

(51) Int. Cl. H01L 21/66; H01L 21/8234; H01L 29/10; H01L 27/11

(52) U.S. Cl. CPC H01L 22/14; H01L 27/1104; H01L 21/823412; H01L 29/1033

(57) ABSTRACT

A method of estimating the capability of a semiconductor manufacturing system is provided. Plural first transistors are formed and a first VtMM value and a first scale value are obtained. Plural second transistors are formed and a second VtMM value and a second scale value are obtained. Plural third transistors are formed and a third VtMM value and a third scale value are obtained. A first channel length of the first transistor is smaller than a second channel length of the second transistor and is equal to a third channel length of the third transistor. A VtMM v.s. scale figure is established. A line is formed by linking the first dot and the third dot and a vertical Gap between the line and the second dot is measured. The capability of the semiconductor system is determined based on the vertical Gap. The invention further provides a chip.

### BACKGROUND OF THE INVENTION

1. Field of the Invention

The present invention relates to a semiconductor chip and a method of estimating the capability of a semiconductor manufacturing system, and more particular, the present invention relates a semiconductor chip with memory arrays and a method of estimating the capability of a semiconductor manufacturing system for forming memory cells.

2. Description of the Prior Art

For decades, chip manufacturers have made metal-oxide-semiconductor (MOS) transistors faster by making them smaller. As the semiconductor processes advance to very deep sub-micron era such as 65-nm node or beyond, how to form smaller device has become a critical issue.

For improving the semiconductor manufacturing system, many parameters should be considered, one of which is “length with roughness (LWR)”. Please see FIG. 1, which shows a schematic diagram of LWR. As shown in FIG. 1, the line pattern is formed after a plurality of semiconductor processes such as deposition, lithography, etching, etc. However, the formed pattern cannot coincide with the original design pattern and have roughness near the edge. In statics, when the pattern has a length CD=20 nanometers, the final formed length may be 18, 21, 20, 16, etc. After calculation, the variation value (a) of the lengths is called “length with roughness (LWR)”. It is understood that the bigger LWR is, the worse the manufacturing process is because it cannot form precise patterns. In some advanced semiconductor process, the effect of LWR (LWR effect) is very important. However, there are few researches relating to the LWR effect and the application of the LWR effect is yet not established.

### SUMMARY OF THE INVENTION

It is therefore one objective of the invention to use the LWR to determine the capability of the semiconductor manufacturing system.

According to one embodiment, a method of estimating the capability of a semiconductor manufacturing system is provided. Plural first transistors are formed and a first VtMM value and a first scale value are obtained. Plural second transistors are formed and a second VtMM value and a second scale value are obtained. Plural third transistors are formed and a third VtMM value and a third scale value are obtained. A first channel length of the first transistor is smaller than a second channel length of the second transistor and is equal to a third channel length of the third transistor. A VtMM v.s. scale figure is established. A line is formed by linking the first dot and the third dot and a vertical Gap between the line and the second dot is measured. The capability of the semiconductor system is determined based on the vertical Gap.

According to another embodiment, the invention further provides a semiconductor chip. The semiconductor chip comprises a plurality of first transistors in a first memory region and a plurality of second transistors in a second memory region, wherein a first channel length of the first transistor is smaller than a second channel length of the second transistor.

By measuring the VtMM and the scale value of the transistors, a “VtMM v.s. scale” figure is established and the Gap is obtained. The Gap represents the LWR and can be used to determine the capability of the semiconductor manufacturing system.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic diagram of LWR.

FIG. 2 shows a flowchart of a method of estimating a capability of a semiconductor manufacturing system according to one embodiment of the present invention.

FIG. 3 to FIG. 9 are schematic diagrams of the method of estimating a capability of a semiconductor manufacturing system according to one embodiment of the present invention.

FIG. 10 shows a schematic diagram of the semiconductor chip according to one embodiment of the present invention.

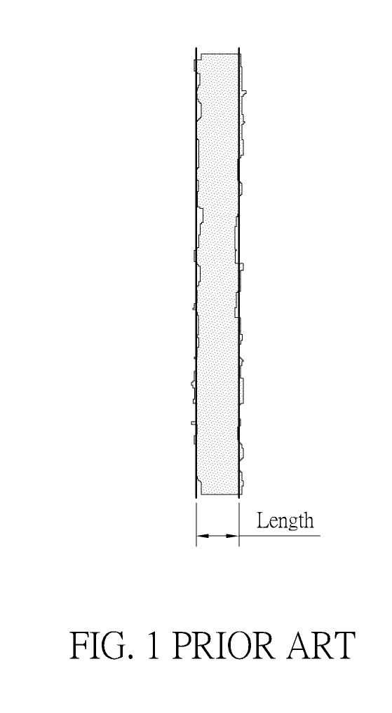

### DETAILED DESCRIPTION

To provide a better understanding of the presented invention, preferred embodiments will be made in detail. The preferred embodiments of the present invention are illustrated in the accompanying drawings with numbered elements.

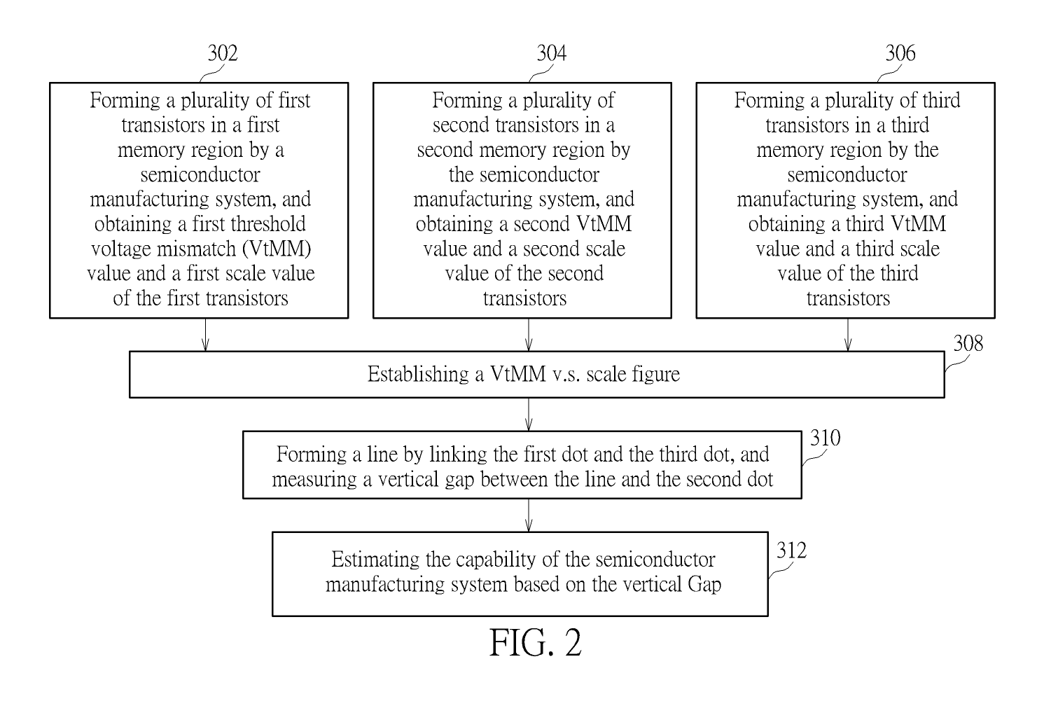

Please refer to FIG. 2, which shows a flowchart of a method of estimating a capability of a semiconductor manufacturing system according to one embodiment of the present invention. As shown in FIG. 2, the method comprises the following steps:

Step 302: forming a plurality of first transistors in a first memory region by a semiconductor manufacturing system, and obtaining a first threshold voltage mismatch (VtMM) value and a first scale value of the first transistors;

Step 304: forming a plurality of second transistors in a second memory region by the semiconductor manufacturing system, and obtaining a second VtMM value and a second scale value of the second transistors;

Step 306: forming a plurality of third transistors in a third memory region by the semiconductor manufacturing system, and obtaining a third VtMM value and a third scale value of the third transistors;

Step 308: establishing a VtMM v.s. scale figure;

Step 310: forming a line by linking the first dot and the third dot, and measuring a vertical gap between the line and the second dot;

Step 312: estimating the capability of the semiconductor system based on the vertical Gap.

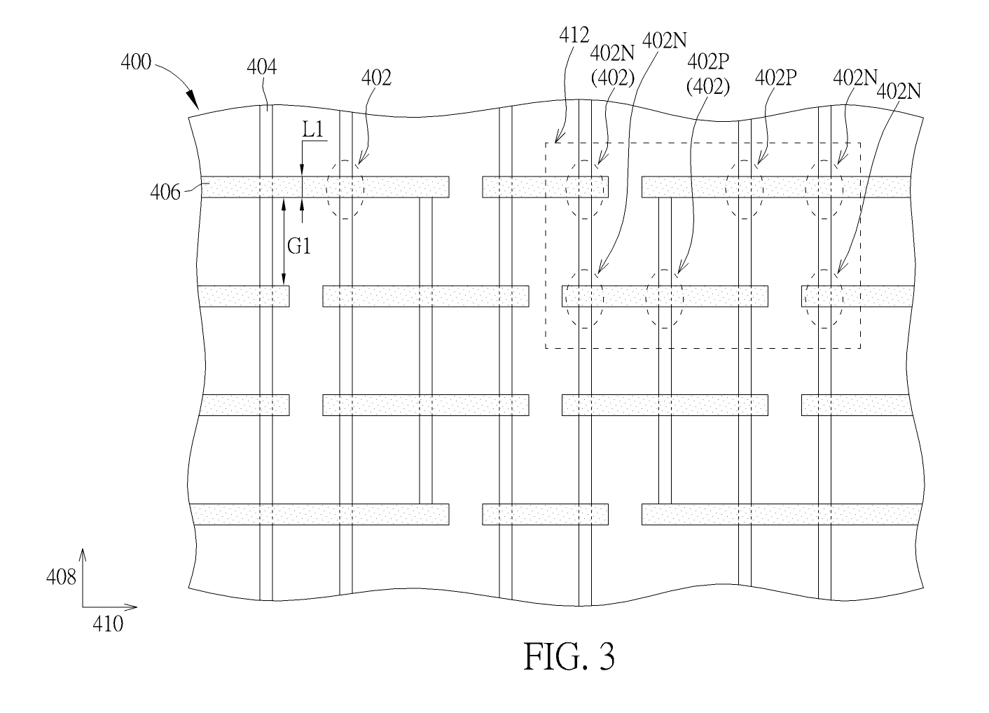

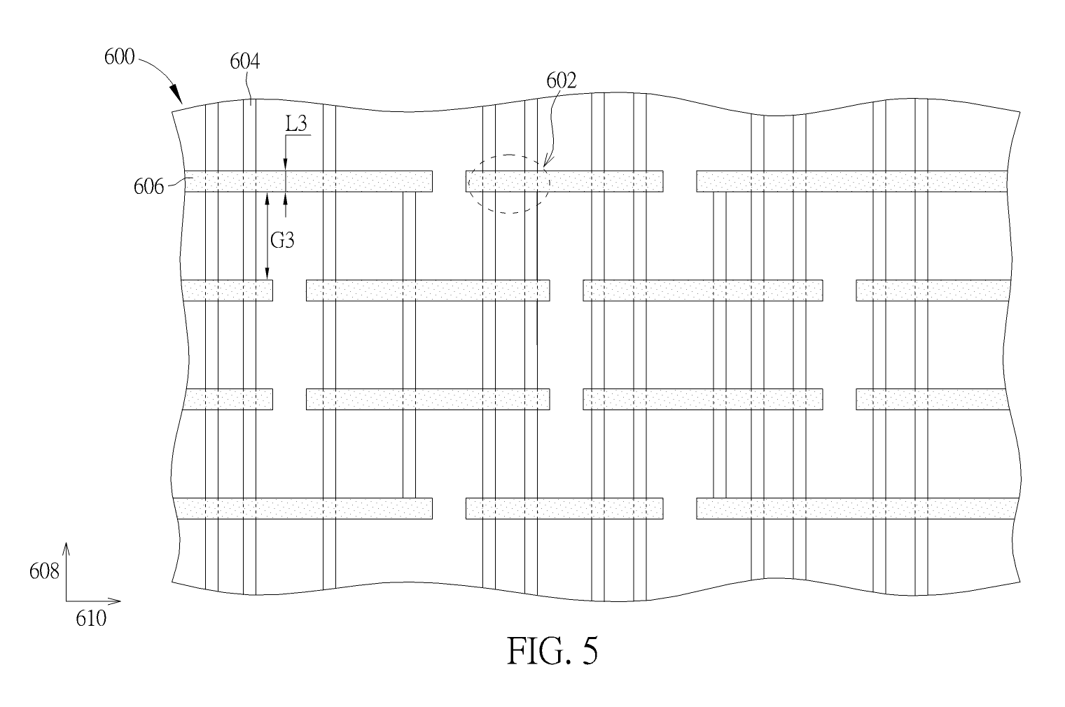

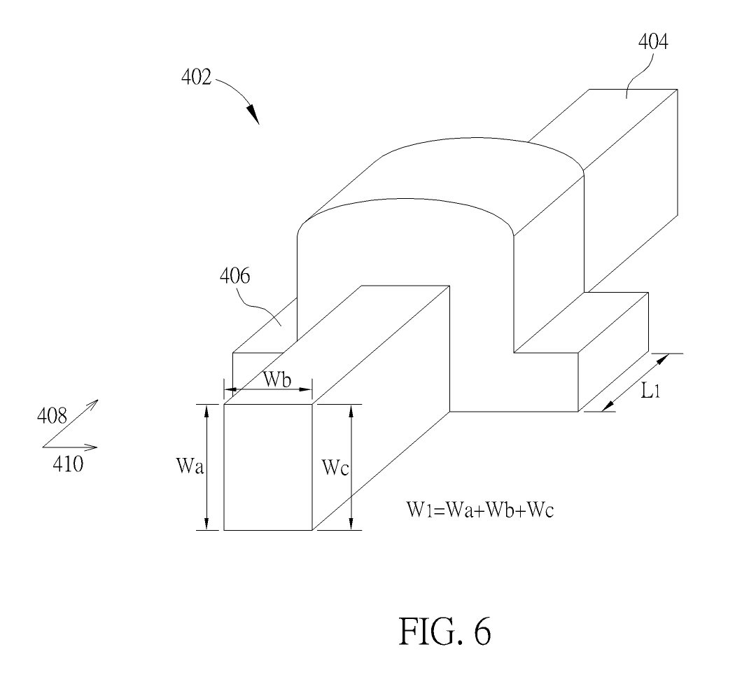

For the detail description of the above-mentioned method, please refer to FIG. 3 to FIG. 9, which are schematic diagrams of the method of estimating a capability of a semiconductor manufacturing system according to one embodiment of the present invention. The method of the present invention starts by providing a plurality of first transistors by a semiconductor manufacturing system (step 302) . In one embodiment, the first transistors are disposed in a first memory region of a wafer (not shown) and more preferably, the first memory region is a Static Random-Access Memory (SRAM) memory region. Please see FIG. 3 for illustrating one embodiment of the first transistors in the first memory region. As shown in a top view of the FIG. 3, a plurality of first transistors 402 are formed in the first memory region 400. In one preferred embodiment, the first memory region 400 is designed as a six-transistor (6T) SRAM region, so in one single first memory cell region 412, there are six first transistors 402 formed therein, with two P-type first transistors 402P and four N-type first transistors 402N. In the present embodiment, the first transistors 402 are Fin-FETs, and a plurality of fin structures 406 and a plurality of gate structures 404, intersecting with each other, are fabricated to form the first transistors 402. The fin structures 404 stretch along a y-direction 408 and the gate structures 406 stretch along an x-direction 410 wherein the x-direction 410 and the y-direction 410 are perpendicular to each other. The first transistor 402 has a first channel length L₁ and a first channel width W₁ (not exactly shown in FIG. 3), and a first gap G1 is between each of the two gate structures 406 along the y-direction 408. For detail descriptions of the channel length and the channel width, please also refer to FIG. 6, which is a schematic diagram of the three dimensional view of the first transistor according to one embodiment of the present embodiment. From the three-dimensional view in FIG. 6, the first transistor 402 is formed by providing the gate structure 406 straddling across the fin structure 404. The first channel length L₁ (also known as agate length) of the first transistor 402 is represented as L₁ in FIG. 5, and the first channel width W, (also known as a gate width) of the first transistor 402 is W₁, which is equal to Wₐ+W_{b}+W_{c} shown in FIG. 5. By knowing the first channel length L₁ and the first channel width W₁, a first scale value can be calculated by the following formula:

The scale value=1/(the channel length×the channel width)^{1/2} (equation 1)

The scale value indicates the scaling down level of a device, and the bigger the scale value is, the smaller the device is. In addition, one or more than one electrical process can be performed to measure a first threshold voltage mismatch (VtMM) of the first transistors 402. The VtMM value is a variation value (a) of the threshold voltages of the first transistors 402. The bigger the VtMM value is, the variation of each Vt is larger, meaning that the semiconductor manufacturing system is poor because all the first transistors should ideally have the same threshold value.

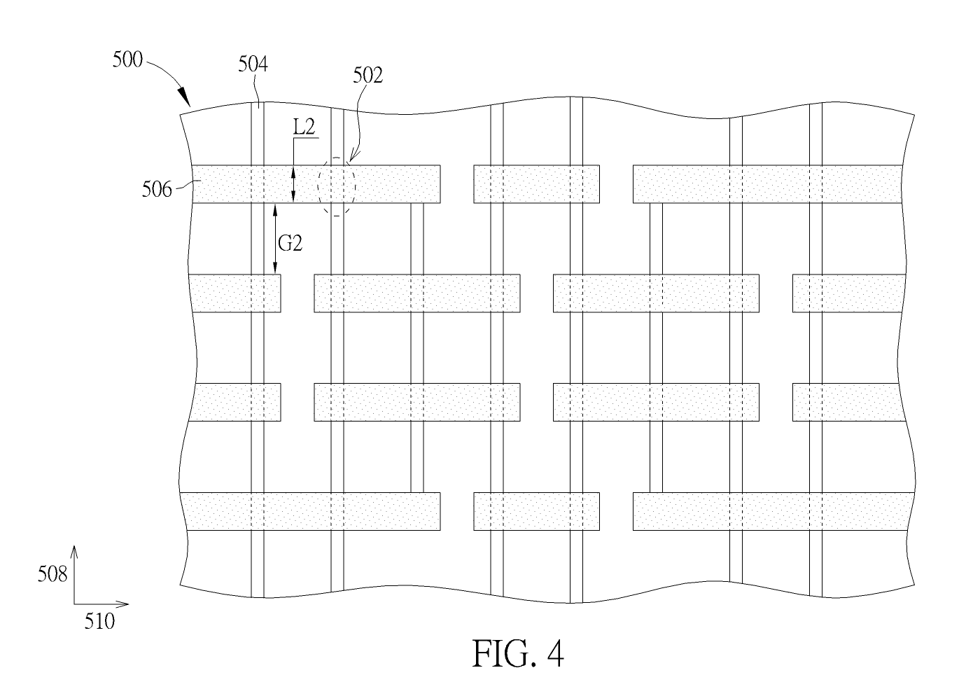

Next, a plurality of second transistors are formed by the same semiconductor manufacturing system for forming the first transistors (step 304). In one embodiment, the second transistors are disposed in a second memory region. Preferably, the second transistors and the second memory region have similar components and arrangements with those of the first transistors and the first memory region. As shown in FIG. 4, the second transistors 502 disposed in the second region 500 are formed with a plurality of fin structures 504 and a plurality of gate structures 506. The fin structures 504 stretch along a y-direction 508 and the gate structures 506 stretch along an x-direction 510 wherein the x-direction 510 and the y-direction 508 are perpendicular to each other. The second transistors 502 has a second channel length L₂ and a second channel width W₂ and a second gap G2 is between each of the two gate structures 506 along the y-direction 508. Since the second transistors 502 have similar structures with the first transistors 402 in one embodiment, the definition of the second channel length L₂ and the second channel width W₂ can refer to FIG. 6. In the present invention, the second channel length L₂ is substantially greater than the first channel length L₁. The second channel width W₂ is equal to the first channel width W₁. The second gap G2 is smaller than the first gap G2. In one embodiment, (G2+L2) is equal to (G1+L1), so the position of the gate structure 508 coincide with that of the gate structure 408. Also, after forming the second transistors 502, the second scale value can be calculated by equation 1 and the second VtMM value can be obtained by a measuring process.

Nest, a plurality of third transistors are formed by the same semiconductor manufacturing system for forming the first transistors (Step 306). The third transistors are disposed in a third memory region. Preferably, the third transistors and the third memory region have the similar components and arrangements with those of the first transistors and the first memory region. As shown in FIG. 5, the third transistors 602 disposed in the third region 500 are formed of a plurality of fin structures 604 and a plurality of gate structures 606. The fin structures 602 stretch along a y-direction 608 and the gate structures 606 stretch along an x-direction 610 wherein the x-direction 610 and the y-direction 608 are perpendicular to each other. The third transistors 602 has a third channel length L₃ and a third channel width W₃ and a third gap G₃ is between each of the two gate structures 606 along the y-direction 608. Because the third transistors 602 has similar structure with the first transistor 402, the definition of the third channel length L₃ and the third channel width W₃ can refer to FIG. 6. However, in this embodiment, the third channel width W₃ is 2*(Wₐ+W_{b}+W_{c}) since two fin structures 604 intersect with one gate structure 606 to form one third transistor 602. In the present invention, the third channel length L₃ is equal to the first channel length L₁. Alternatively, the second channel width W₂ is greater than the first channel width W₁ (twice of the first channel width W₁ in this embodiment). The third gap G₃ is equal to the first gap G₁. Also, after forming the third transistors 602, the third scale value can be calculated by equation 1 and the third VtMM value can be obtained by a measuring process.

It is noted further noted that that the sequence of forming the first transistors 402, the second transistors 502 and the third transistors 602 can be adjusted arbitrarily or they can be formed simultaneously if they are in the same wafer.

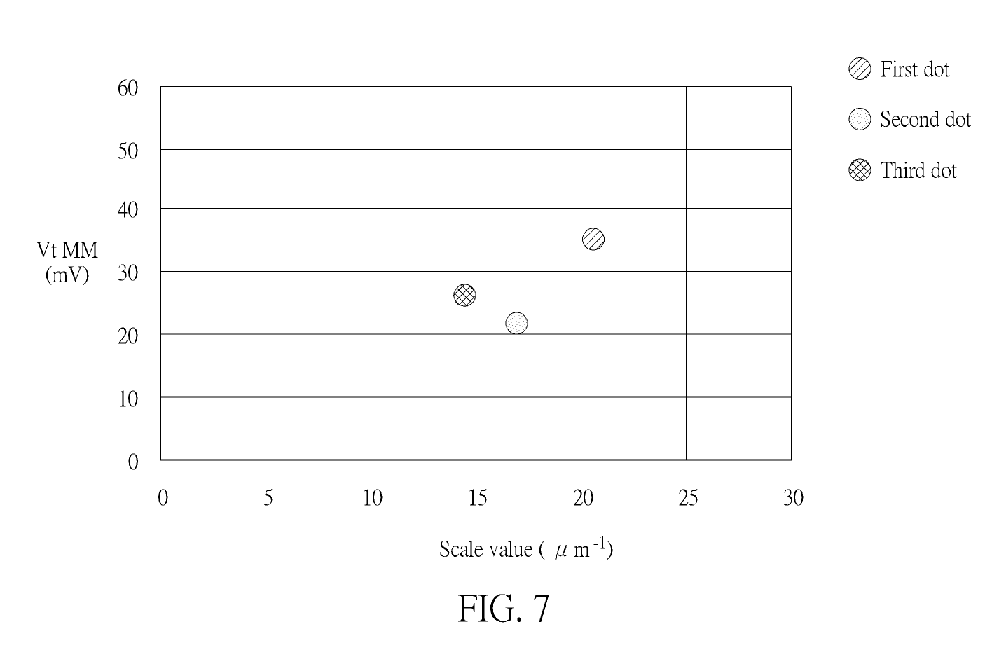

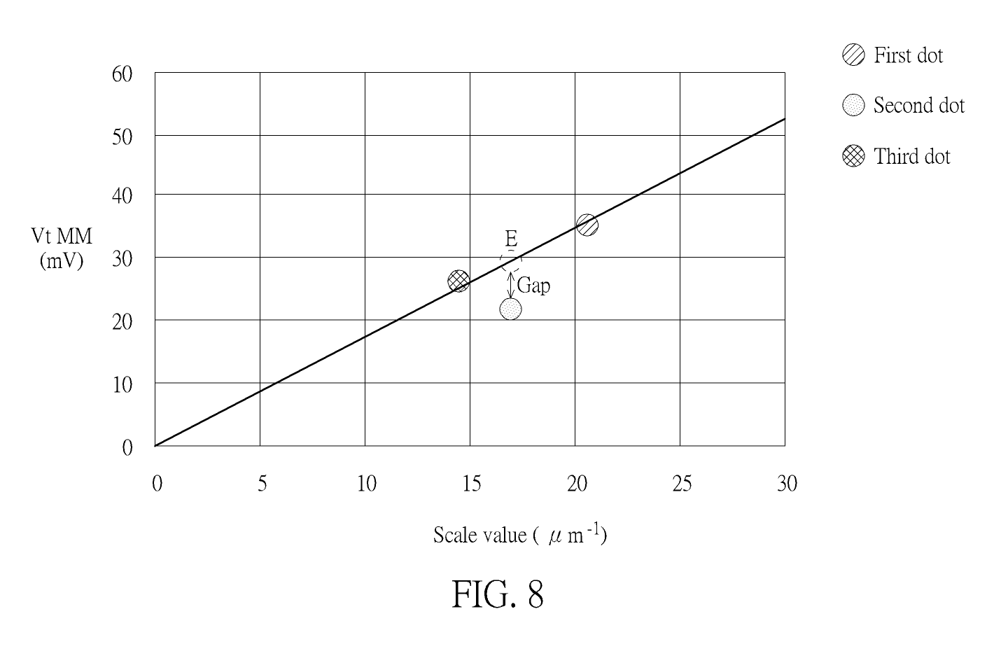

After obtaining the first scale value, the first VtMM value, the second scale value, the second VtMM value, the third scale value and the third VMM value, a “VtMM v.s. scale” figure can be established (step 308). Please see FIG. 7 and FIG. 8, showing the “VtMM v.s. scale value” figure in the present invention. Please see FIG. 7. The x-axis refers to the scale value with a unit μm⁻¹, and the y-axis refers to the VtMM with a unit mV. A first dot corresponding to the first VtMM value and the first scale value of the first transistor 402 is plotted to the figure. A second dot corresponding to the second VtMM and the second scale value of the second transistor 502 is plotted to the figure. A third dot corresponding to the third VtMM value and the third scale value of the third transistor 602 is plotted to the figure. Therefore, the “VtMM v.s. scale” figure is established.

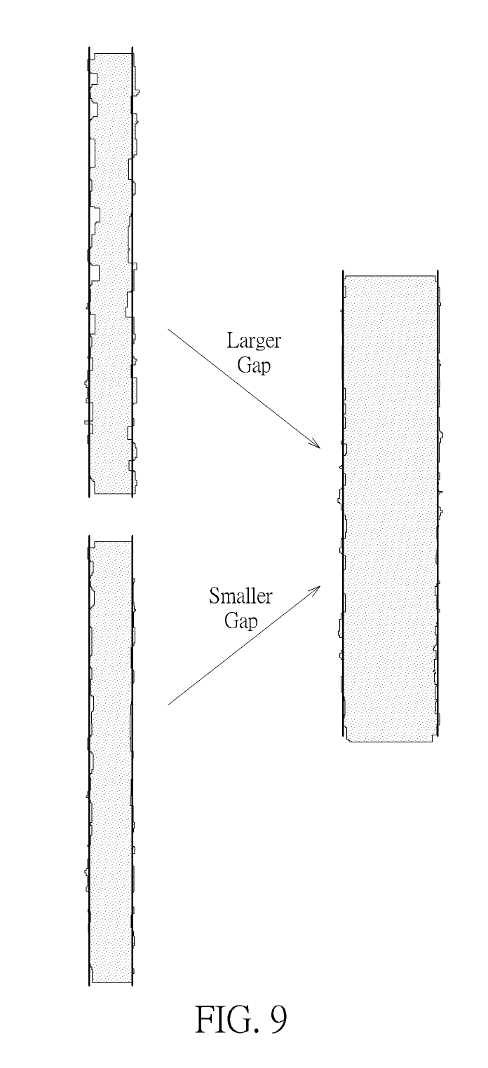

Next, as shown in FIG. 8, aline is formed by linking the first dot and the third dot. Thereafter, a vertical Gap between the line and second dot is measured (step 310). The Gap is one indicative parameter of the “LWR effect.” Briefly speaking, because the first transistors 402 and the third transistors 602 have the same channel length (L₁=L₃), there is no LWR effect therebetween. However, since the second transistor 502 has a larger channel length (L₂>L₁), the LWR effect would happen and cause the second spot originally on the line to shift downwardly to this position. That is to say, if the second transistor have the same second length with the first transistor or the third transistor (L1=L2=L3), all of whom would stand on the same line shown in FIG. 8, because they are formed by the same semiconductor manufacturing system. However, when the channel width is enlarged (like the second transistor), it is found that the VtMM of the second transistors 502 is decreased (the decrease value is the Gap), meaning that the devices are improved. The decrease phenomenon is resulted from the LWR effect. Please see FIG. 9, which shows a schematic diagram comparing a larger Gap and a smaller Gap. As shown in FIG. 9, in the upper part, if the semiconductor manufacturing system is poor, the formed pattern will have rough edge and the VtMM of the device is higher, after enlarging the CD (the right part), since the semiconductor manufacturing system can more easily reach the enlarged CD, the device of the VtMM is lower. The Gap thereof is large. On the other hand, in the lower part of FIG. 9, if the semiconductor manufacturing system is good, the formed pattern is smoother and even when enlarging the CD, the formed pattern is still smooth. Thus, a difference between the VtMM value is not large so the Gap in FIG. 8 is small.

Accordingly, the Gap can be used to estimate the capability of the semiconductor manufacturing system for forming the first transistors 402, the second transistors 502 and the third transistors 602 (step 312). If the Gap is within an acceptable value, the semiconductor manufacturing system is capable of performing processes with least errors. However, if the Gap exceeds an acceptable value, it means that the LWR effect is too large and the semiconductor manufacturing system should be reconsidered because it cannot form precise pattern. By providing the above-mentioned process, the LWR can be easily obtained by measuring the Gap so as to estimate the capability of the semiconductor manufacturing system.

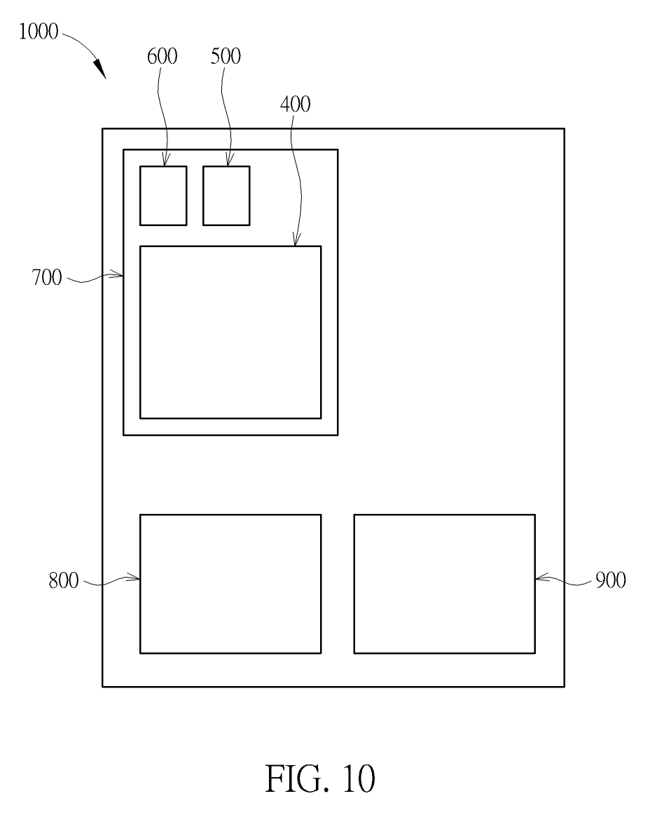

It is noted that, in the present invention, the first transistors 402, the second transistors 502 and the third transistors 602 are not necessary in the same wafer or die. In one embodiment, they are in the same wafer or die, and in another embodiment, two of whom are in the same wafer or die. In one embodiment, by performing the method shown above, the second transistors 502 are used as a “testkey” structure in a small region, together with the mass-produced first transistors 402 and/or the mass-produced third transistors 602, so as to perform the method in the present invention. Accordingly, the present invention further provides a chip structure with the above features. Please see FIG. 10, which shows a schematic diagram of the semiconductor chip according to one embodiment of the present invention. As shown in FIG. 10, in the semiconductor chip 1000, the first memory region 400, the second memory region 500 and the third memory region 600 are all in a memory region 700. In one embodiment, there are only memory cells instead of other passive or active components disposed therein in the memory region 700. The first transistors 402 are in the first memory region 400, the second transistors 502 are in the second memory region 500 and the third transistors are in the third memory region 600. In some embodiments, the third transistor 600 can be omitted. The detail descriptions of the first transistors 402, the second transistors 502 and the third transistors 602 are shown above, and are not repeated. It is one salient feature that first channel length L₁ of the first transistor 402 is different from the second channel length L₂ of the second transistor 502. In one embodiment, the die 1000 can further has a CPU region 800 and/or a FR region 900, but is not limited thereto.

In summary, the present invention provides a semiconductor chip and a method of monitoring the LWR value in a semiconductor manufacturing system. By measuring the VtMM and the scale value of the transistors, a “VtMM v.s. scale” figure is established and the Gap is obtained. The Gap represents the LWR and can be used to determine the capability of the semiconductor manufacturing system.

Those skilled in the art will readily observe that numerous modifications and alterations of the device and method may be made while retaining the teachings of the invention. Accordingly, the above disclosure should be construed as limited only by the metes and bounds of the appended claims.

1. A method of estimating the capability of a semiconductor manufacturing system, comprising:
forming a plurality of first transistors in a first memory region by using a semiconductor manufacturing system, and obtaining a first VtMM value and a first scale value based on the first transistors;
forming a plurality of second transistors in a second memory region by using the semiconductor manufacturing system, and obtaining a second VtMM value and a second scale value based on the second transistors;
forming a plurality of third transistors in a third memory region by using the semiconductor manufacturing system, and obtaining a third VtMM value and a third scale value based on the third transistors, wherein a first channel length of the first transistor is smaller than a second channel length of the second transistor and is equal to a third channel length of the third transistor;
establishing a VtMM v.s. scale figure and plotting a first dot corresponding to the first VtMM value and the first scale value, a second dot corresponding to the second VtMM and the second scale value, and a third dot corresponding to the third VtMM value and the third scale value on said figure;
forming a line by linking the first dot and the third dot;
measuring a vertical Gap between the line and the second dot; and
estimating the capability of the semiconductor system based on the vertical Gap.

2. The method of estimating the capability of a semiconductor manufacturing system according to claim 1, wherein the first memory region, the second memory region and the third memory region are in a memory region.

3. The method of estimating the capability of a semiconductor manufacturing system according to claim 2, wherein the memory region is a Static Random-Access Memory (SRAM) memory region.

4. The method of estimating the capability of a semiconductor manufacturing system according to claim 2, wherein the memory region is a 6-transistors (6T) SRAM memory cell region.

5. The method of estimating the capability of a semiconductor manufacturing system according to claim 1, wherein each first transistor further comprises a first channel width, each second transistor further comprises a second channel width, and each third transistor further comprises a third channel width.

6. The method of estimating the capability of a semiconductor manufacturing system according to claim 5, wherein the first channel width is equal to the second channel width.

7. The method of estimating the capability of a semiconductor manufacturing system according to claim 5, wherein the first channel width is smaller than the third channel width.

8. The method of estimating the capability of a semiconductor manufacturing system according to claim 5, wherein the first scale value, the second scale value and the third scale value are obtained by the following equation:
the scale value=1/(the channel length×the channel width)^{1/2}

9. The method of estimating the capability of a semiconductor manufacturing system according to claim 1, wherein the first VtMM value, the second VtMM value and the third VtMM value are variation values of the threshold voltage of the first transistors, the second transistors and the third transistors respectively.

10. The method of estimating the capability of a semiconductor manufacturing system according to claim 1, wherein the larger the Gap is, the less capability of the semiconductor manufacturing system is.

11. A semiconductor chip, comprising a plurality of first transistors in a first memory region and a plurality of second transistors in a second memory region, wherein each first transistor has a first gate structure and each second transistor has a second gate structure, and a first gap is disposed between each of two adjacent first gate structures and a second gap is disposed between each of the two adjacent second gate structures, a first channel length of the first transistor is smaller than a second channel length of the second transistor, and (the first channel length+the first gap)=(the second channel length+the second gap).

12. The semiconductor chip according to claim 11, wherein the first memory cell region and the second memory cell region are in a memory region.

13. The semiconductor chip according to claim 12, wherein the memory region is a Static Random-Access Memory (SRAM) memory region.

14. The semiconductor chip according to claim 12, wherein the memory region is a 6-transistors (6T) SRAM memory cell region.

15. (canceled)

16. The semiconductor chip according to claim 11, further comprising a plurality of third transistors in a third memory region.

17. The semiconductor chip according to claim 11, wherein a third channel length of the third transistor is equal to the first channel length.

18. The semiconductor chip according to claim 11, wherein each first transistor further comprises a first channel width, each second transistor further comprises a second channel width, and each third transistor further comprises a third channel width.

19. The semiconductor chip according to claim 18, wherein the first channel width is equal to the second channel width.

20. The semiconductor chip according to claim 18, wherein the first channel width is smaller than the third channel width.
